(19) United States
(12) Patent Application Publication
(10) Pub. No.: US 2021/0111139 A1
(43) Pub. Date: Apr. 15, 2021

(54) SEMICONDUCTOR DEVICE PACKAGES AND METHODS OF MANUFACTURING THE SAME

(71) Applicant: Advanced Semiconductor Engineering, Inc., Kaohsiung (TW)

(72) Inventor: Hsu-Nan FANG, Kaohsiung (TW)

(73) Assignee: Advanced Semiconductor Engineering, Inc., Kaohsiung (TW)

(21) Appl. No.: 16/597,720

(22) Filed: Oct. 9, 2019

(51) Int. Cl. H01L 23/00; H01L 23/31; H01L 23/538; H01L 21/48; H01L 21/56

(52) U.S. Cl. CPC H01L 24/16; H01L 23/3128; H01L 23/3135; H01L 23/5383; H01L 23/5386; H01L 2224/16503; H01L 21/4857; H01L 21/563; H01L 21/565; H01L 2224/10126; H01L 2224/16227; H01L 21/4853

(57) ABSTRACT

A semiconductor device package includes a redistribution layer, a first semiconductor device, a first connection structure, and a first conductive layer. The first semiconductor device can be disposed on the redistribution layer. The first connection structure can be disposed between the first semiconductor device and the redistribution layer. The first conductive layer can surround the first connection structure.

### BACKGROUND

### 1. Field of the Disclosure

The present disclosure relates to semiconductor device packages and methods of manufacturing the same.

### 2. Description of Related Art

A semiconductor device package can include a semiconductor device bonded or attached to a carrier by connection material. However, the connection material, e.g. solder material, may have relatively great resistance which results in heat and relatively less signal transmission speed.

### SUMMARY

According to some example embodiments of the instant disclosure, a semiconductor device package includes a redistribution layer, a first semiconductor device, a first connection structure, and a first conductive layer. The first semiconductor device can be disposed on the redistribution layer. The first connection structure can be disposed between the first semiconductor device and the redistribution layer. The first conductive layer can surround the first connection structure.

According to some example embodiments of the instant disclosure, a semiconductor device package includes a first conductive pad, a second conductive pad, and a first conductive layer. The first conductive pad may have a first lateral surface. The second conductive pad can be disposed on the first conductive pad and may have a first lateral surface. The first conductive layer can be disposed in direct contact with the first lateral surface of the first conductive pad and the first lateral surface of the second conductive pad.

According to some example embodiments of the instant disclosure, a method of manufacturing a semiconductor device package includes forming a first connection structure to electrically connect a semiconductor device to an redistribution layer; forming a second connection structure to electrically connect the semiconductor device to the redistribution layer; forming a conductive layer to surround the first connection structure.

### BRIEF DESCRIPTION OF THE DRAWINGS

Aspects of the present disclosure are readily understood from the following detailed description when read with the accompanying figures. It should be noted that various features may not be drawn to scale. In fact, the dimensions of the various features may be arbitrarily increased or reduced for clarity of discussion.

FIG. 1A is a cross-sectional view of a semiconductor device package in accordance with some embodiments of the present disclosure.

FIG. 1B is an enlarged view of a structure in dotted box A as shown in FIG. 1A.

FIG. 1C is an enlarged view of a structure in dotted box B as shown in FIG. 1A.

FIG. 2A is a top view of the structure in dotted box A as shown in FIG. 1A.

FIG. 2B is another top view of the structure in dotted box A as shown in FIG. 1A.

FIG. 2C is another top view of the structure in dotted box A as shown in FIG. 1A.

FIG. 2D is another top view of the structure in dotted box A as shown in FIG. 1A.

FIG. 3A is another enlarged view of the structure in dotted block A as shown in FIG. 1A.

FIG. 3B is another enlarged view of the structure in dotted block A as shown in FIG. 1A.

FIG. 3C is another enlarged view of the structure in dotted block A as shown in FIG. 1A.

FIG. 3D is another enlarged view of the structure in dotted block A as shown in FIG. 1A.

FIG. 4A, FIG. 4B, FIG. 4C, FIG. 4D, FIG. 4E, FIG. 4F, FIG. 4G, FIG. 4H, FIG. 4I, FIG. 4J and FIG. 4K illustrate various stages of a method for manufacturing a semiconductor device package accordance with some embodiments of the subject application.

FIG. 5A, FIG. 5B, FIG. 5C and FIG. 5D illustrate various stages of another method for manufacturing a semiconductor device package accordance with some embodiments of the subject application.

### DETAILED DESCRIPTION

The following disclosure provides for many different embodiments, or examples, for implementing different features of the provided subject matter. Specific examples of components and arrangements are described below. These are, of course, merely examples and are not intended to be limiting. In the present disclosure, reference to the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Embodiments of the present disclosure are discussed in detail below. It should be appreciated, however, that the present disclosure provides many applicable concepts that can be embodied in a wide variety of specific contexts. The specific embodiments discussed are merely illustrative and do not limit the scope of the disclosure.

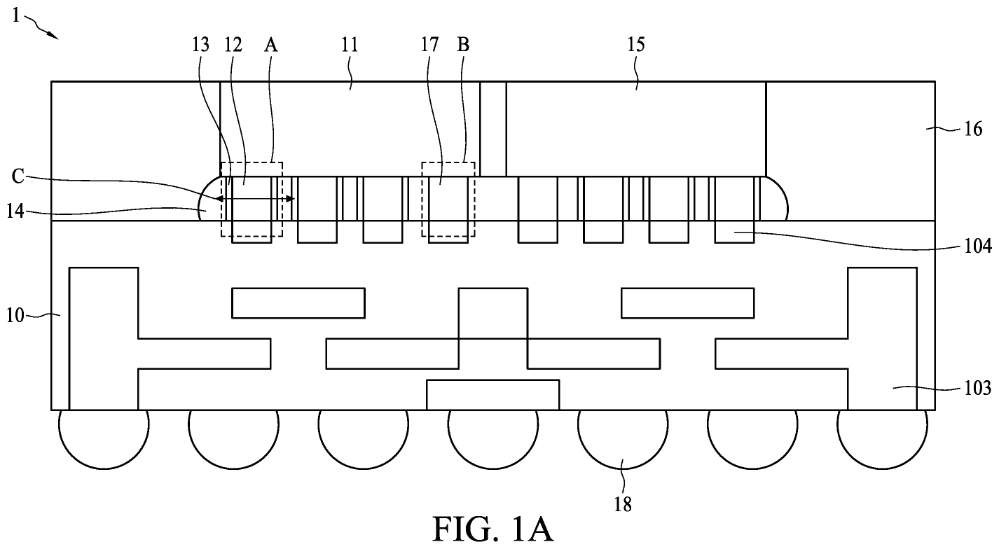

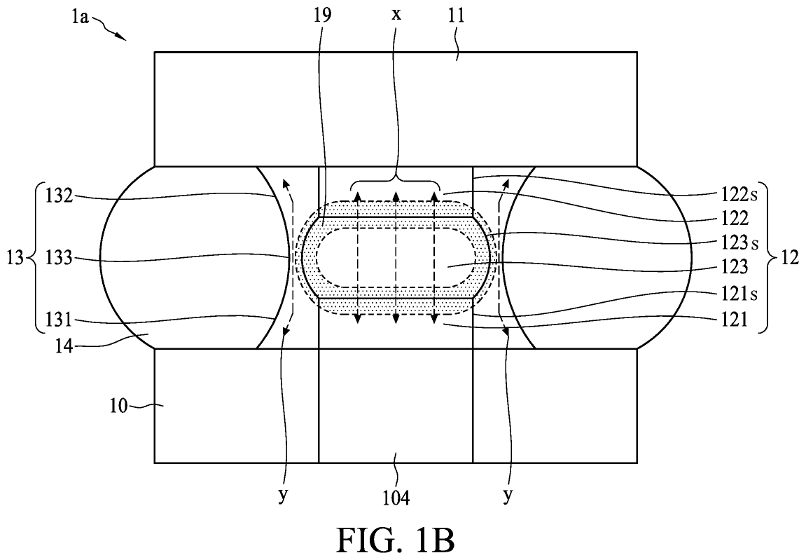

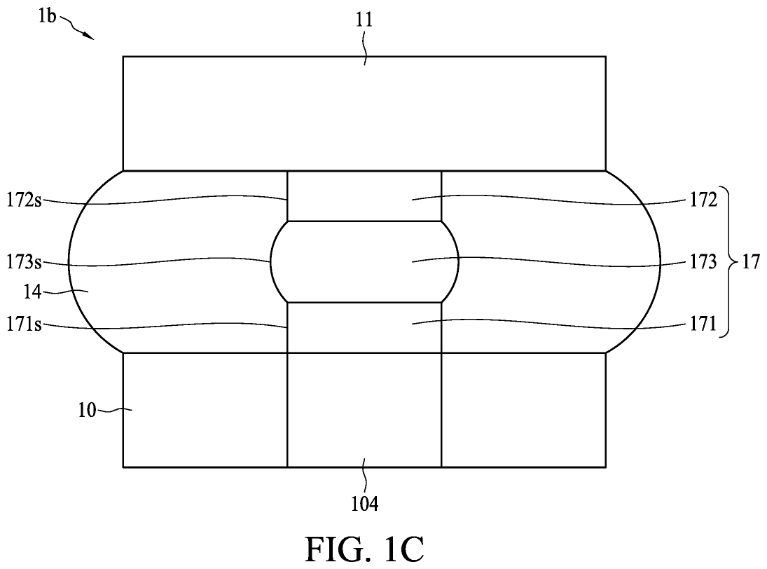

FIG. 1A is a cross-sectional view of a semiconductor device package in accordance with some embodiments of the present disclosure.

Referring to FIG. 1A, the semiconductor device package 1 may include a redistribution layer 10, a semiconductor device 11, a connection structure 12, a conductive layer 13, an encapsulant 14, another semiconductor device 15, an insulation body 16, another connection structure 17, and connection components 18.

The redistribution layer 10 can include a redistribution structure 103 or circuitry 103. The redistribution layer 10 can include a single layer structure. The redistribution layer 10 can include a multi-layer structure. The redistribution layer 10 can include a substrate. The redistribution layer 10 can include a fan-out structure. The redistribution layer 10 may include insulation material(s) or dielectric material(s) (not denoted in FIG. 1A). The redistribution layer 10 can include a core or relatively hard material. The redistribution layer 10 can include flexible or relatively soft material.

The redistribution structure 103 can include a some conductive elements, for example but is not limited to, conductive trace(s), pad(s), contact(s) (e.g. conductive contacts 104), via(s).

The redistribution structure 103 can have a pitch equal to or less than approximately 12 micrometers (μm). The redistribution structure 103 can have a line width/space equal to or less than approximately 12/12 μm. The redistribution structure 103 can have a pitch equal to or less than approximately 10 μm. The redistribution structure 103 can have a line width/space equal to or less than approximately 10/10 μm. The redistribution structure 103 can have a pitch equal to or less than approximately 8 μm. The redistribution structure 103 can have a line width/space equal to or less than approximately 8/8 μm. The redistribution structure 103 can have a pitch equal to or less than approximately 5 μm. The redistribution structure 103 can have a line width/space equal to or less than approximately 5/5 μm. The redistribution structure 103 can have a pitch equal to or less than approximately 2 μm. The redistribution structure 103 can have a line width/space equal to or less than approximately 2/2 μm.

The semiconductor device 11 can be disposed on the redistribution layer 10. The semiconductor device 11 may include, for example but is not limited to, a processor, a controller (e.g. a memory controller), a microcontroller (MCU), a memory die, a power device, a high-speed input/output device or other electronic component(s). The semiconductor device 11 can be electrically connected to the redistribution layer 10. The semiconductor device 11 can include the connection structure 12.

The semiconductor device 11 can be bonded or attached to the redistribution layer 10 by the connection structure 12. The semiconductor device 11 can be bonded or attached to the conductive contacts 104 of the redistribution layer 10 by the connection structure 12.

The connection structure 12 can be disposed on the redistribution layer 10. The connection structure 12 can be disposed between the semiconductor device 11 and the redistribution layer 10. The connection structure 12 can bond or attach the semiconductor 11 to the redistribution layer 10. The connection structure 12 can bond or attach the semiconductor 11 to the conductive contacts 104 of the redistribution layer 10.

The connection structures 12 can connect the semiconductor device 11 with the redistribution layer 10. The connection structure 12 can be electrically conductive. The connection structure 12 may include, for example but is not limited to, solder, adhesive (which may include conductive adhesive (e.g. resin mixed with conductive particles)), or other suitable bonding material(s).

The connection structures 12 can be surrounded by the conductive layer 13. The connection structures 12 can be enclosed by the conductive layer 13. The connection structures 12 can be in direct contact with the conductive layer 13.

The conductive layer 13 can be disposed on the redistribution layer 10. The conductive layer 13 can be disposed between the semiconductor device 11 and the redistribution layer 10. The conductive layer 13 can surround the connection structure 12. The conductive layer 13 can enclose the connection structure 12. The conductive layer 13 can be disposed in direct contact with the connection structure 12. The conductive layer 13 may include a single layer structure. The conductive layer 13 can include a multi-layer structure. The conductive layer 13 may include a barrier layer. The conductive layer 13 may include, for example but is not limited to, nickel, copper, gold, platinum or other suitable metal material(s).

The conductive layer 13 can be electrically conductive. The conductive layer 13 may have relatively great electrical conductivity. The conductive layer 13 may have relatively greater electrical conductivity than the connection structure 12. The conductive layer 13 may have relatively less resistivity. The conductive layer 13 may have resistivity less than about 5*10⁻⁶ Ω-cm. The conductive layer 13 may have resistivity in the range from about 1*10⁻⁸ Ω-cm to about 1*10⁻⁷ Ω-cm. The conductive layer 13 may have resistivity of about 1*10⁻Ω-cm. The conductive layer 13 may have relatively less resistivity than the connection structure 12.

The conductive layer 13 can be thermal conductive. The conductive layer 13 may have relatively great thermal conductivity. The conductive layer 13 may have thermal conductivity greater than about 100 Wm⁻¹K⁻¹. The conductive layer 13 may have thermal conductivity in the range from about 100 Wm⁻¹K⁻¹ to about 400 Wm⁻¹K⁻¹. The conductive layer 13 may have thermal conductivity of about 400 Wm⁻¹K⁻¹. The conductive layer 13 may have relatively greater thermal conductivity than the connection structure 12.

The encapsulant 14 can be disposed on the redistribution layer 10. The encapsulant 14 can be disposed between the semiconductor device 11 and the redistribution layer 10. The encapsulant 14 can surround the connection structure 12. The encapsulant 14 can encapsulate the conductive layer 13. A portion of the encapsulant 14 can extend between the redistribution layer 10 and the semiconductor device 11 and function as a mold lock. The encapsulant 14 can include epoxy. The encapsulant 14 can include underfill material. The encapsulant 14 can include molding compound (e.g. epoxy molding compound (EMC)) or encapsulation material.

The semiconductor device 15 can be disposed on the redistribution layer 10. The semiconductor device 15 may include, for example but is not limited to, a processor, a controller (e.g. a memory controller), a microcontroller (MCU), a memory die, a power device, a high-speed input/output device or other electronic component(s).

The semiconductor device 15 can be bonded or attached to the redistribution layer 10 by the connection structures 12. The semiconductor device 11 can be bonded or attached to the conductive contacts 104 of the redistribution layer 10 by the connection structures 12.

The semiconductor device 11 can be the same or similar to the semiconductor device 15. The semiconductor device 11 can be different from the semiconductor device 15.

Although two semiconductor devices 11 and 15 are illustrated in FIG. 1A, however, it is contemplated that the semiconductor device package 1 can include more or less semiconductor devices in some other embodiments of the subject application.

The insulation body 16 can be disposed on the redistribution layer 10. The insulation body 16 can encapsulate the semiconductor device 11. The insulation body 16 can encapsulate the semiconductor device 12. The insulation body 15 can encapsulate the encapsulant 14. The insulation body 16 can surround the semiconductor device 11. The insulation body 16 can surround the semiconductor device 12.

The insulation body 16 can include insulation or dielectric material. The insulation body 16 can include resin (e.g. bismaleimide triazine resin (BT). The insulation body 16 can include fillers or particles (e.g. SiO₂ particles) (not shown in FIG. 1A). The insulation body 16 can include epoxy. The insulation body 15 can include underfill material. The insulation body 16 can include molding compound (e.g. epoxy molding compound (EMC)) or encapsulation material.

The semiconductor device 11 can be bonded or attached to the redistribution layer 10 by the connection structure 17. The semiconductor device 11 can be bonded or attached to the conductive contacts 104 of the redistribution layer 10 by the connection structure 17.

The semiconductor device 15 can be bonded or attached to the redistribution layer 10 by the connection structure 17. The semiconductor device 15 can be bonded or attached to the conductive contacts 104 of the redistribution layer 10 by the connection structure 17.

The connection structure 17 can be disposed on the redistribution layer 10. The connection structure 17 can be disposed between the semiconductor device 11 and the redistribution layer 10. The connection structures 17 can bond or attach the semiconductor 11 to the redistribution layer 10. The connection structure 17 can bond or attach the semiconductor 11 to the conductive contacts 104 of the redistribution layer 10.

The connection structures 17 can connect the semiconductor device 11 with the redistribution layer 10. The connection structure 17 can be electrically conductive. The connection structure 17 may include, for example but is not limited to, solder, adhesive (which may include conductive adhesive (e.g. resin mixed with conductive particles)), or other suitable bonding material(s).

The connection structure 17 can be exposed to the encapsulant 14. The connection structure 17 can be surrounded by the encapsulant 14. The connection structure 17 can be enclosed by the encapsulant 14. The connection structure 17 can be disposed in direct contact with the encapsulant 14. The encapsulant 14 can encapsulate the connection structure 17.

The connection components 17 can be disposed on the redistribution layer 10. The connection components 17 can include solder or other suitable bonding material(s).

FIG. 1B is an enlarged view of structure in dotted box A as shown in FIG. 1A.

Referring to FIG. 1B, the structure 1a can include the connection structure 12. The connection structure 12 can include a conductive pad 121, a conductive pad 122 and a connection element 123.

The conductive pad 121 can be disposed on the redistribution layer 10. The conductive pad 121 can be disposed on the conductive contact 104. The connection structure 12 can be disposed between the redistribution layer 10 and the semiconductor device 11. The conductive pad 121 can be disposed between the connection element 123 and the conductive contact 104.

The conductive pad 121 can have a lateral surface 121s. The lateral surface 121s can be surrounded by the conductive layer 13. The lateral surface 121s can be enclosed by the conductive layer 13. The lateral surface 121s can be in direct contact with conductive layer 13.

The conductive pad 121 can include a single layer structure. The conductive pad 121 can include a multi-layer structure. The conductive pad 121 can be electrically conductive. The conductive pad 121 may have relatively great electrical conductivity. The connection element 123 may have relatively less resistivity. The conductive pad 121 may have relatively less resistivity than the connection element 123. The conductive pad 121 may include a barrier layer. The conductive pad 121 may include a seed layer. The conductive pad 122 may include a conductive layer. The conductive pad 122 may include, for example but is not limited to, titanium, tungsten, nickel, copper, gold, platinum or other suitable metal material(s).

The conductive pad 122 can be disposed on the redistribution layer 10. The conductive pad 122 can be disposed on the conductive pad 121. The conductive pad 122 can be disposed adjacent to the semiconductor device 11. The connection pad 122 can be disposed between the redistribution layer 10 and the semiconductor device 11. The conductive pad 122 can be disposed between the connection element 123 and the semiconductor device 11.

The conductive pad 122 can have a lateral surface 122s. The lateral surface 122s can be surrounded by the conductive layer 13. The lateral surface 122s can be enclosed by the conductive layer 13. The lateral surface 122s can be in direct contact with the conductive layer 13.

The conductive pad 122 can include a single layer structure. The conductive pad 122 can include a multi-layer structure. The connection element 122 may have relatively less resistivity. The conductive pad 122 may have relatively less resistivity than the connection element 123. The conductive pad 122 may include a barrier layer. The conductive pad 122 may include a seed layer. The conductive pad 122 may include a conductive layer. The conductive pad 122 may include, for example but is not limited to, titanium, tungsten, nickel, copper, gold, platinum or other suitable metal material(s).

The connection element 123 can be disposed on the redistribution layer 10. The connection element 123 can be disposed between the redistribution layer 10 and the semiconductor device 11. The connection element 123 can be disposed between the conductive pad 121 and the conductive pad 122.

The connection element 123 can be electrically connected to the conductive pad 121. The connection element 123 can be electrically connected to the conductive pad 122. The connection element 123 can be electrically conductive. The connection element 123 may have relatively less electrical conductivity. The connection element 123 may have relatively great resistivity. The connection element 123 may have resistivity greater than about 5*10⁻⁶ Ω-cm. The connection element 123 may have resistivity greater than about 10*10⁻⁶ Ω-cm. The connection element 123 may have resistivity in the range from about 6*10⁻⁶ Ω-cm to about 14.5*10⁻⁶ Ω-cm. The connection element 123 may have resistivity about 11.5*10⁻⁶ Ω-cm.

The connection element 123 may have relatively less thermal conductivity. The connection element 123 may have thermal conductivity less than about 80 Wm⁻¹K⁻¹. The connection element 123 may have thermal conductivity in the range from about 60 Wm⁻¹K⁻¹ to about 78 Wm⁻¹K⁻¹.

The connection element 123 may include, for example but is not limited to, solder, adhesive (which may include conductive adhesive (e.g. resin mixed with conductive particles)), or other suitable bonding material(s).

The connection element 123 may include different material from the conductive pad 121. The connection element 123 may include different material from the conductive pad 122. The conductive pad 121 may include different material from the conductive pad 122. The conductive pad 121 may include material same or similar to the conductive pad 122.

The connection element 123 can have a lateral surface 123s. The lateral surface 123s can be surrounded by the conductive layer 13. The lateral surface 123s can be enclosed by the conductive layer 13. The lateral surface 123s can be in direct contact with the conductive layer 13.

The arrow x can represent a conductive path through the connection structure 12 (e.g., the conductive pad 121, the conductive pad 122, or the connection element 123). For example, the arrow x can show the transmission between the redistribution layer 10 and the semiconductor device 11. In other words, the redistribution layer 10 can communicate with the semiconductor device 11 via the connection structure 12. A current can be transmitted from the redistribution layer 10 to the semiconductor device 11 via the connection structure 12. A current can be transmitted from the semiconductor device 11 to the redistribution layer 10 via the connection structure 12.

The connection element 123 of the connection structure 12 may cause relatively great RC delay. The connection element 123 of the connection structure 12, which can have relatively great resistivity, may slow the transmission speed. Furthermore, the connection element 123 of the connection structure 12, which can have relatively less thermal conductivity, may have adverse effect on the heat dissipation. The connection element 123 with relatively less thermal conductivity may induce overheat issues, electromigration or device reliability issues.

The arrow y can represent a conductive path in the conductive layer 13. For example, the arrow y can show the transmission between the redistribution layer 10 and the semiconductor device 11. In other words, the redistribution layer 10 can communicate with the semiconductor device 11 via the conductive layer 13. A current can be transmitted from the redistribution layer 10 to the semiconductor device 11 via the conductive layer 13. A current can be transmitted from the semiconductor device 11 to the redistribution layer 10 via the conductive layer 13.

The conductive layer 13, which can have relatively less resistivity, may lead to relatively less RC delay. The conductive layer 13 may improve the transmission speed between the redistribution layer 10 and the semiconductor device 11. The conductive layer 13 may allow relatively great current between the redistribution layer 10 and the semiconductor device 11.

The conductive layer 13 which can have relatively great thermal conductivity may improve the heat dissipation to avoid overheat electromigration or device reliability issues.

Assuming the conductive layer 13 fails due to crack or other issues, the connection structure 12 can still provide the conductive path (the arrow x in FIG. 1B). Assuming the connection structure 12 fails due to crack or other issues, the conductive layer 13 can still provide the conductive path (the arrow y in FIG. 1B). Design of the connection structure 12 and the conductive layer 13 can secure the transmission between the semiconductor device 11 and the redistribution layer 10.

The conductive layer 13 can have different thicknesses or different shapes to reduce the resistance of the conductive layer 13. The conductive layer 13 can have different thicknesses or different shapes to increase the cooling area of the conductive layer 13.

The conductive layer 13 can have a neck 133. The conductor layer 13 can have a curved surface.

The conductive layer 13 can include a portion 131. The portion 131 can be adjacent to the redistribution layer 10. The portion 131 can be tapering. The portion 131 can have a trapezoidal shape. The portion 131 can surround the conductive pad 121. The portion 131 can enclose the conductive pad 121. The portion 131 can be in direct contact with the conductive pad 121.

The conductive layer 13 can include a portion 132. The portion 132 can be adjacent to the semiconductor device 11. The portion 132 can be tapering. The portion 132 can have a trapezoidal shape. The portion 132 can surround the conductive pad 122. The portion 132 can enclose the conductive pad 121. The portion 132 can be in direct contact with the conductive pad 122.

The conductive layer 13 can include a portion 133. The portion 133 can be adjacent to the portion 131. The portion 133 can be adjacent to the portion 132. The portion 133 can have a neck. The portion 133 can surround the connection element 123. The portion 133 can enclose the connection element 123. The portion 133 can be in direct contact with the connection element 123.

The portion 131 can have a width different from the portion 133. The portion 131 can have a width greater than the portion 133. The portion 132 can have a width different from the portion 133. The portion 132 can have a width greater than the portion 133. The portion 131 can have a width same or similar to the portion 132.

Referring to FIG. 1B, the conductive layer 13 can include an intermetallic compound (IMC) structure 19. The IMC structure 19 can be disposed between the connection structure 12 and the conductive layer 13. The IMC structure 19 can surround the connection structure 12. The IMC structure 19 can enclose the connection structure 12. The IMC structure can be formed in the connection structure 12. The IMC structure can be formed in the conductive layer 13. The IMC structure can be disposed between the connection element 123 and the portion 131. The IMC structure can be disposed between the connection element 123 and the portion 132. The IMC structure can be disposed between the connection element 123 and the portion 133. The connection element 123 may include the IMC structure 19. The portion 133 may include the IMC structure 19.

The IMC structure 19 may be resulted from the interaction between the connection structure 12 and the conductive layer 13. The IMC structure 19 may include a Cu, Ni, Sn combination or an Au, Sn combination. The region enclosed by the two dotted ovals in FIG. 1B denotes, for example but is not limited to, the topography of the IMC structure 19. The IMC structure 19 may be formed discontinuously. That is, the IMC structure 19 may be discontinuous or may not have a consistent thickness. The IMC structure 19 may increase mechanical reliability. The IMC structure 19 may improve the physical connection between the conductive layer 13 and the connection structure 12.

FIG. 1C is an enlarged view of the structure in dotted box B as shown in FIG. 1A.

Referring to FIG. 1C, the semiconductor device package 1b can be similar to the semiconductor device package 1a in FIG. 1A as described and illustrated with reference to FIG. 1A, except that the conductive layer 13 can be eliminated. The encapsulant 14 can surround the connection structure 17. The encapsulant 14 can enclose the connection structure 17. The encapsulant 14 can be disposed in direct contact with the connection structure 17. The encapsulant 14 can encapsulant the connection structure 17.

Referring to FIG. 1C, the connection structure 17 can include a conductive pad 171, a conductive pad 172 and a connection element 173.

The conductive pad 171 can be disposed on the redistribution layer 10. The conductive pad 171 can be disposed on the conductive contact 104. The connection structure 12 can be disposed between the redistribution layer 10 and the semiconductor device 11. The conductive pad 171 can be disposed between the connection element 173 and the conductive contact 104.

The conductive pad 171 can have a lateral surface 171s. The lateral surface 171s can be surrounded by the encapsulant 14. The lateral surface 171s can be enclosed by the encapsulant 14. The lateral surface 171s can be in direct contact with the encapsulant 14. The lateral surface 171s can be encapsulated by the encapsulant 14.

The conductive pad 171 can include a single layer structure. The conductive pad 171 can include a multi-layer structure. The conductive pad 171 can be electrically conductive. The conductive pad 171 may have relatively great electrical conductivity. The conductive pad 171 may have relatively greater electrical conductivity than the connection element 173. The conductive pad 171 may include a barrier layer. The conductive pad 171 may include a seed layer. The conductive pad 172 may include a conductive layer. The conductive pad 172 may include, for example but is not limited to, titanium, tungsten, nickel, copper, gold, platinum or other suitable metal material(s).

The conductive pad 172 can be disposed on the redistribution layer 10. The conductive pad 172 can be disposed on the conductive pad 171. The conductive pad 172 can be disposed adjacent to the semiconductor device 11. The connection structure 17 can be disposed between the redistribution layer 10 and the semiconductor device 11. The conductive pad 172 can be disposed between the connection element 173 and the semiconductor device 11.

The conductive pad 172 can have a lateral surface 172s. The lateral surface 172s can be surrounded by the encapsulant 14. The lateral surface 172s can be enclosed by the encapsulant 14. The lateral surface 172s can be in direct contact with the encapsulant 14. The lateral surface 172s can be encapsulated by the encapsulant 14.

The conductive pad 172 can include a single layer structure. The conductive pad 172 can include a multi-layer structure. The conductive pad 172 can be electrically conductive. The conductive pad 172 may include a barrier layer. The conductive pad 172 may include a seed layer. The conductive pad 172 may include a conductive layer. The conductive pad 172 may include, for example but is not limited to, titanium, tungsten, nickel, copper, gold, platinum or other suitable metal material(s).

The connection element 173 can be disposed on the redistribution layer 10. The connection element 173 can be disposed between the redistribution layer 10 and the semiconductor device 11. The connection element 173 can be disposed between the conductive pad 171 and the conductive pad 172.

The connection element 173 can have a lateral surface 173s. The lateral surface 173s can be surrounded by the encapsulant 14. The lateral surface 173s can be enclosed by the encapsulant 14. The lateral surface 173s can be in direct contact with the encapsulant 14. The lateral surface 173s can be encapsulated by the encapsulant 14.

The connection element 173 may include, for example but is not limited to, solder, adhesive (which may include conductive adhesive (e.g. resin mixed with conductive particles)), or other suitable bonding material(s).

The connection element 173 may include different material from the conductive pad 171. The connection element 173 may include different material from the conductive pad 172. The conductive pad 171 may include different material from the conductive pad 172. The conductive pad 171 may include material same or similar to the conductive pad 172.

The structure 1b can be applied to the connection which may specify relatively less transmission speed. The structure 1b can be applied to the connection which may specify relatively less current.

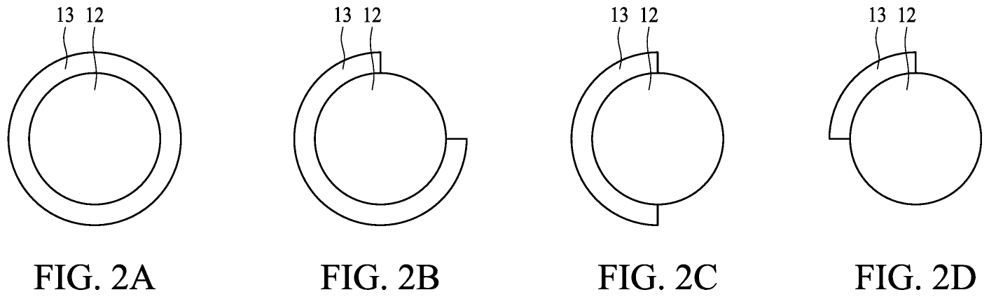

FIG. 2A is a top view of the structure in dotted box A as shown in FIG. 1A.

Referring to FIG. 2A, the conductive layer 13 can include a ring or ring-like structure. The conductive layer 13 can surround the connection structure 12. The conductive layer 13 can cover the connection structure 12. The conductive layer 13 can cover approximately 100% of the surface of the connection structure 12. The conductive layer 13 can cover 90%-100% of the surface of the connection structure 12.

FIG. 2B is another top view of the structure in dotted box A as shown in FIG. 1A.

Referring to FIG. 2B, the conductive layer 13 can cover a part of the surface of the connection structure 12. The conductive layer 13 can cover approximately 75% of the surface of the connection structure 12. The conductive layer 13 can cover from about 60% to about 90% of the surface of the connection structure 12.

FIG. 2C is another top view of the structure in dotted box A as shown in FIG. 1A.

Referring to FIG. 2C, the conductive layer 13 can cover a part of the surface of the connection structure 12. The conductive layer 13 can cover approximately 50% of the surface of the connection structure 12. The conductive layer 13 can cover from about 40% to about 60% of the surface of the connection structure 12.

FIG. 2D is another top view of the structure in dotted box A as shown in FIG. 1A.

Referring to FIG. 2D, the conductive layer 13 can cover a part of the surface of the connection structure 12. The conductive layer 13 can cover approximately 25% of the surface of the connection structure 12. The conductive layer 13 can cover from about 5% to about 40% of the surface of the connection structure 12.

The connection structure 12 can have a cylinder structure. Depending on the fabrication or layout, the connection structure 12 can also have, for example but is not limited to, an elliptic cylinder structure, a triangular prism structure, cuboid structure, pentagonal prism structure or other suitable structures.

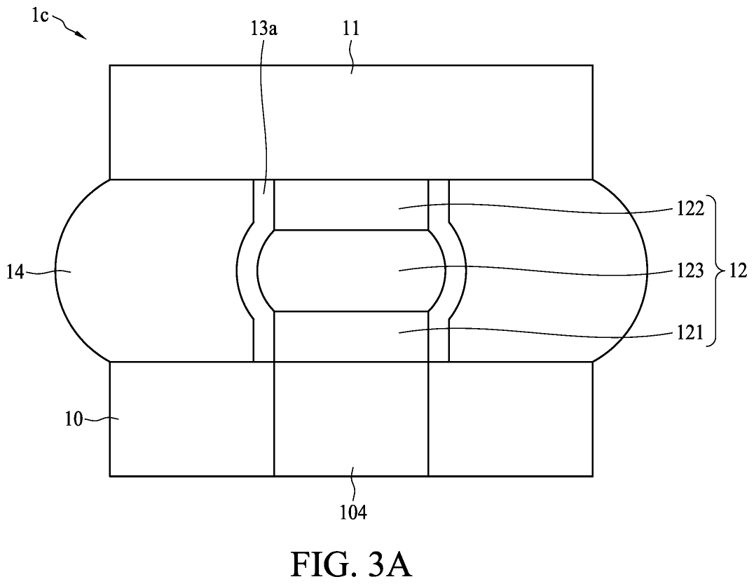

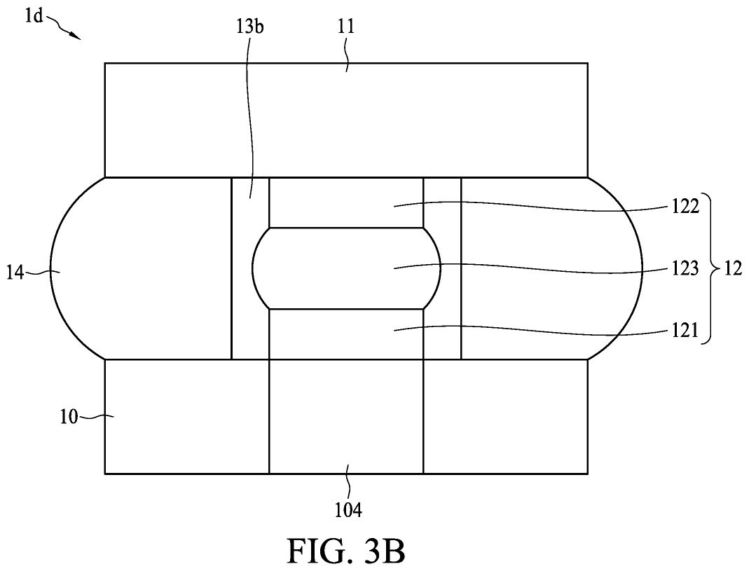

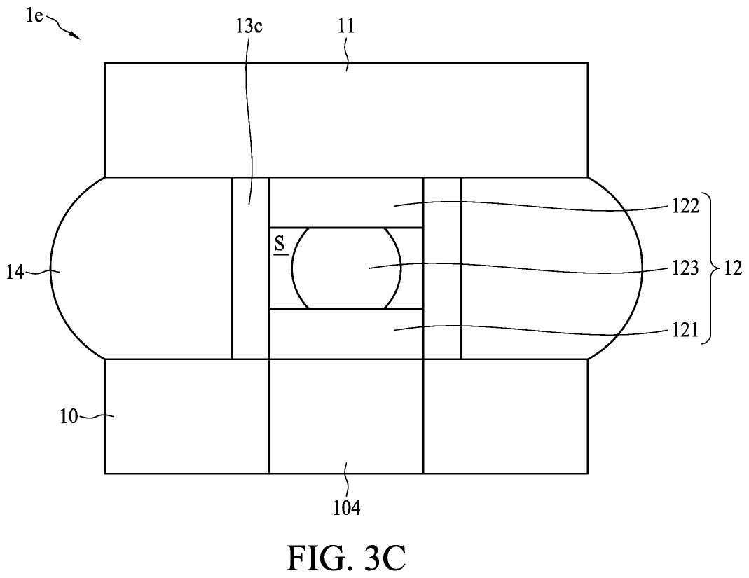

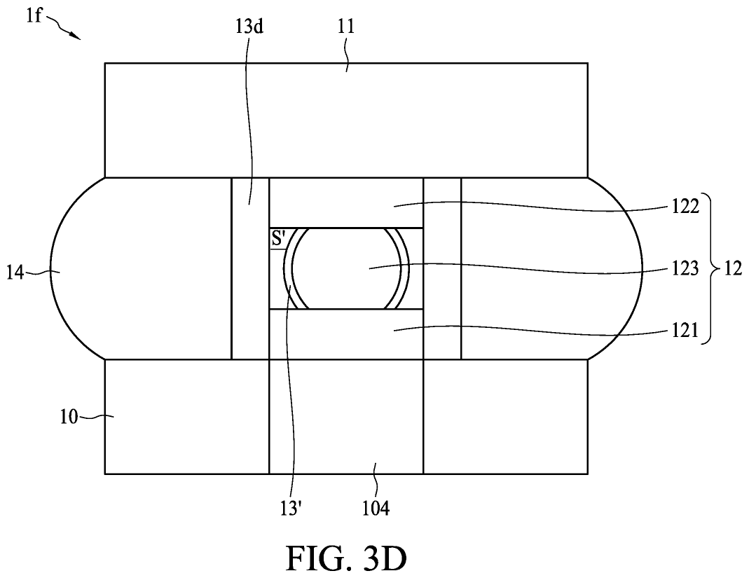

FIG. 3A is another enlarged view of the structure in dotted block A as shown in FIG. 1A.

Referring to FIG. 3A, the structure 1c can be similar to the structure 1a in FIG. 1A as described and illustrated with reference to FIG. 1A, except that the structure 1c can have a conductive layer 13a.

FIG. 3B is another enlarged view of the structure in dotted block A as shown in FIG. 1A.

Referring to FIG. 3B, the structure 1d can be similar to the structure 1a in FIG. 1A as described and illustrated with reference to FIG. 1A, except that structure 1d can have a conductive layer 13b.

FIG. 3C is another enlarged view of the structure in dotted block A as shown in FIG. 1A.

Referring to FIG. 3C, the semiconductor device package 1e can be similar to the semiconductor device package 1a in FIG. 1A as described and illustrated with reference to FIG. 1A, except that a space S can be defined by the connection structure 12 and a conductive layer 13c.

FIG. 3D is another enlarged view of the structure in dotted block A as shown in FIG. 1A.

Referring to FIG. 3D, the semiconductor device package if can be similar to the semiconductor device package 1a in FIG. 1A as described and illustrated with reference to FIG. 1A, except that a space S′ can be defined by the connection structure 12, a conductive layer 13d, and a conductive layer 13′.

The conductive layer 13′ can surround the connection element 123. The conductive layer 13′ can enclose the connection element 123. The conductive layer 13′ can be in direct contact with the connection element 123. The conductive layer 13′ can be surrounded by the conductive layer 13.

The conductive layer 13′ may include IMC structure. The IMC structure may include a Cu, Ni, Sn combination. The conductive layer 13′ may include a barrier layer. The conductive layer 13′ may include a conductive layer. The conductive layer 13′ may include, for example but is not limited to, nickel, copper, gold, platinum or other suitable metal material.

The conductive layers 13a, 13b, 13c, 13d, and 13′ can have material the same or similar to the conductive layers 13. The conductive layers 13a, 13b, 13c, 13d, and 13′ can have material different from the conductive layers 13.

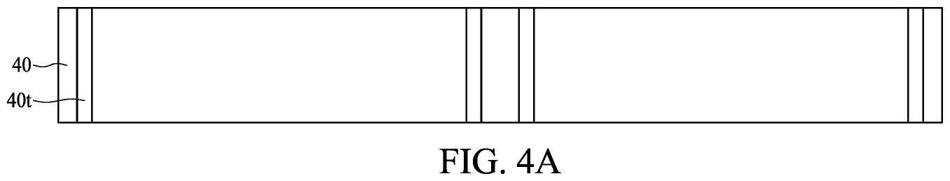

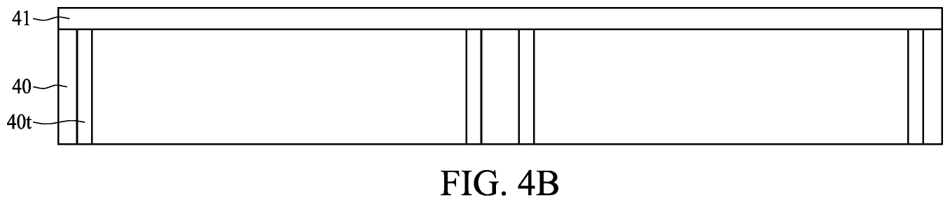

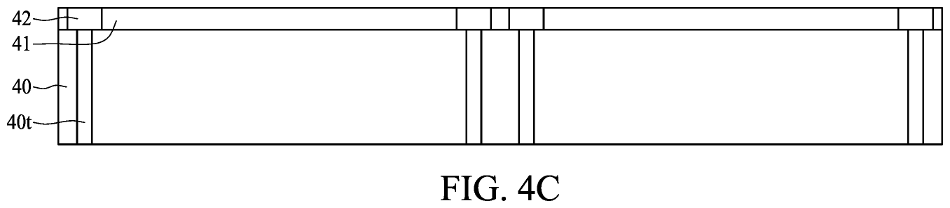

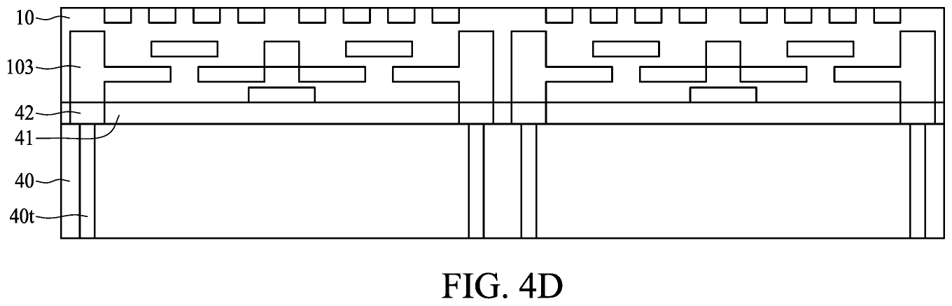

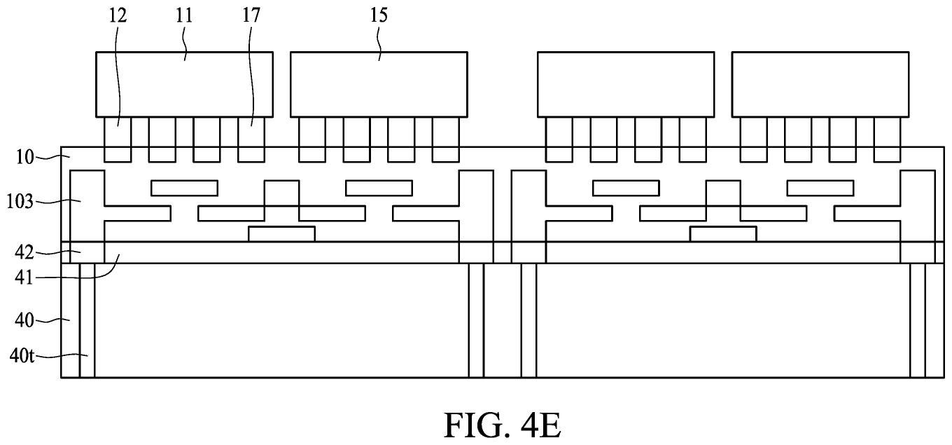

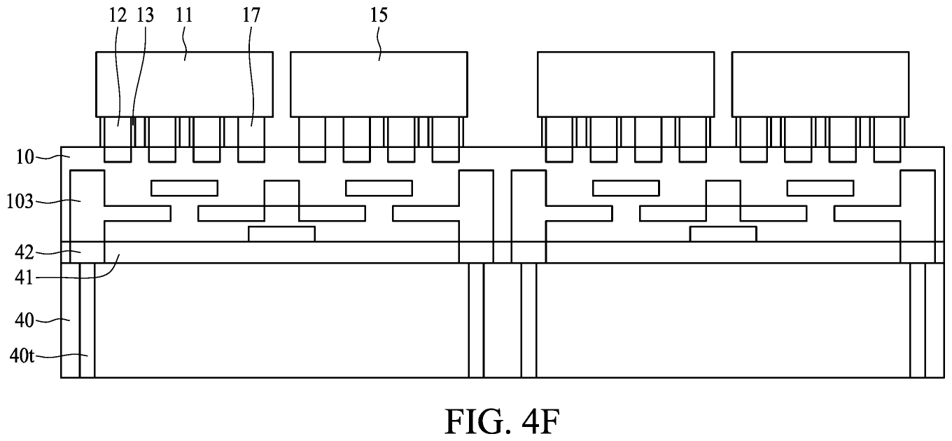

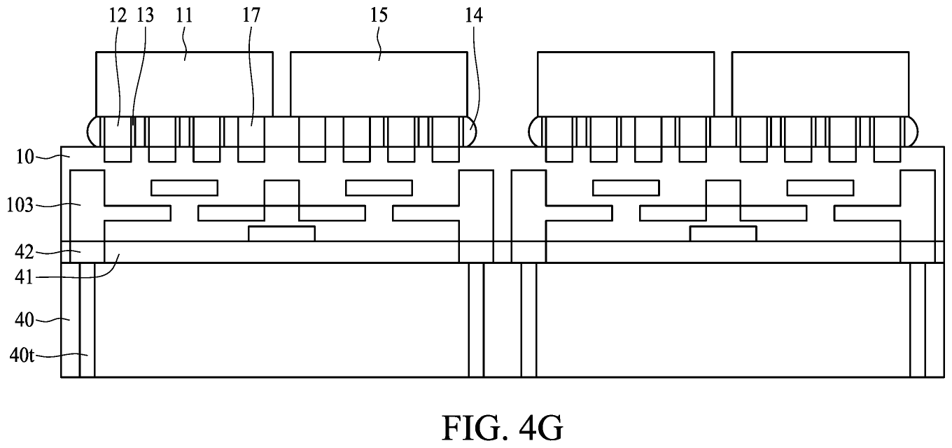

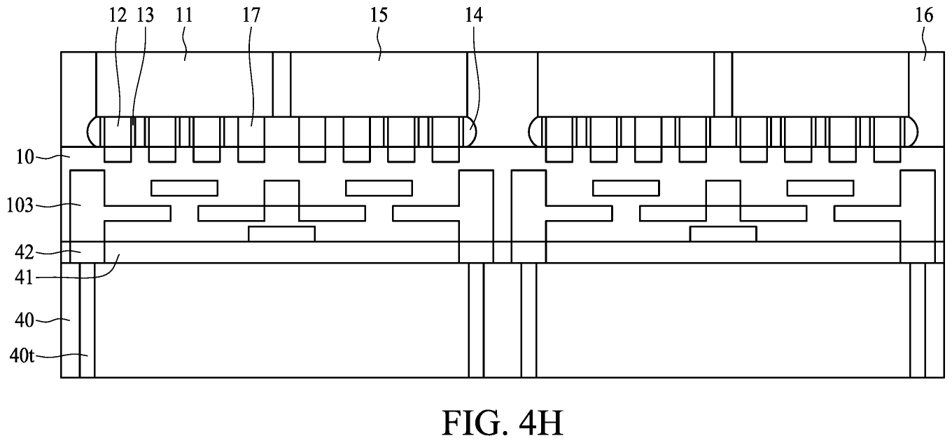

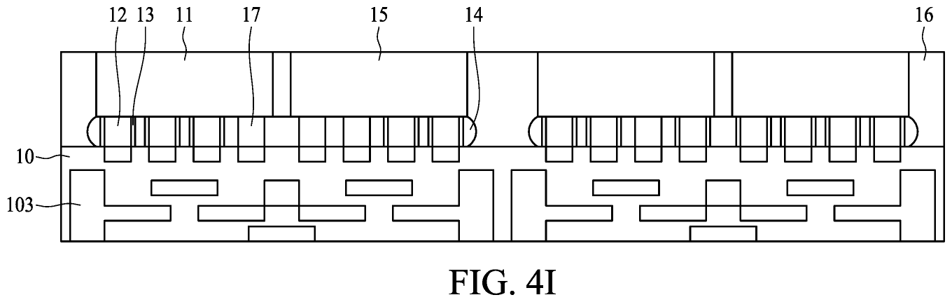

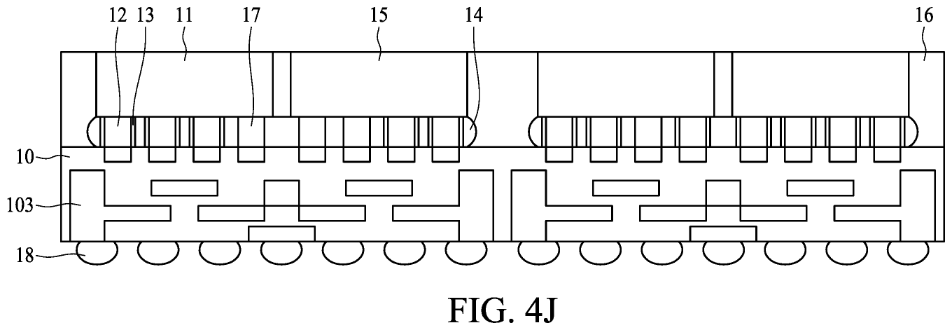

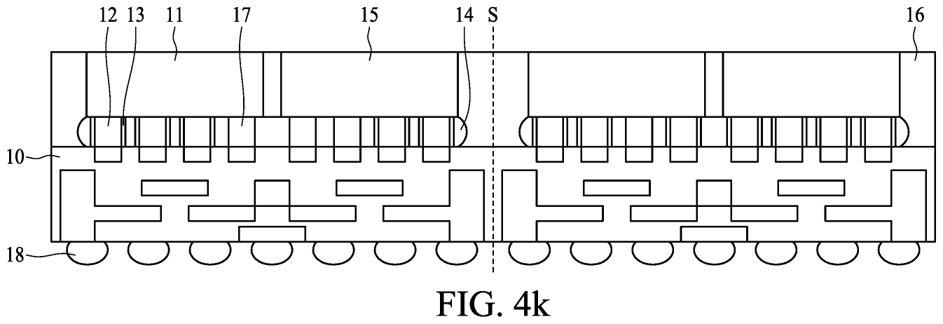

FIG. 4A, FIG. 4B, FIG. 4C, FIG. 4D, FIG. 4E, FIG. 4F, FIG. 4G, FIG. 4H, FIG. 4I, FIG. 4J and FIG. 4K illustrate various stages of a method for manufacturing a semiconductor device package accordance with some embodiments of the subject application.

Referring to FIG. 4A, a carrier 40 can be provided. The carrier 40 can include a via 40t. The carrier can be glass. The via 40t can be through glass via (TGV).

Referring to FIG. 4B, a release layer 41 can be formed on the carrier 40.

Referring to FIG. 4C, a release layer 41 can be patterned to form a trench and expose the via 40t. A seed layer 42 can be formed in the trench. The seed layer 42 can be formed on the via 40t.

Referring to FIG. 4D, a redistribution layer 10 can be formed on the carrier 40. The redistribution layer 10 can include a redistribution structure 103. The redistribution structure can be connected with the seed layer 42. The redistribution layer 10 can be electrically connected to the via 40t.

Referring to FIG. 4E, a semiconductor device 11 can be attached or bonded on the redistribution layer 10 by a connection structure 12 or a connection structure 17. The connection structure 12 can be formed to electrically connect the semiconductor device 11 to the redistribution layer 10. The connection structure 17 can be formed to electrically connect the semiconductor device 11 to the redistribution layer 10. The semiconductor device 11 can be attached or bonded through the flip-chip bonding (FCB) technique.

More semiconductor devices (e.g., a semiconductor device 15) can be also attached or bonded on the redistribution layer 10 by the connection structure 12 or the connection structure 17.

Referring to FIG. 4F, a conductive layer 13 can be formed to surround the connection structure 12. The conductive layer 13 can be formed to enclose the connection structure 12. The conductive layer 13 can be formed in direct contact with the connection structure 12.

The conductive layer 13 can be formed by electroplating. The conductive layer 13 can be formed by multilayer electroplating. During the electroplating of the conductive layer 13, an electroplating voltage can apply on the connection structure 12, so that the conductive layer 13 can be formed to surround the connection structure 12.

Referring to FIG. 4G, an encapsulant 14 can be formed between the semiconductor devices 11 and 15 and the redistribution layer 10.

Referring to FIG. 4H, an insulation body 16 can be formed on the redistribution layer 10 and to encapsulate the semiconductor devices 11 and 15 and the encapsulant 14.

Referring to FIG. 4I, the carrier 40, the release layer 41, the seed layer 42 can be removed.

Referring to FIG. 4J, some connection components 18 may be formed on the redistribution layer 10. The connection components 18 can be electrically connected to redistribution layer 10.

Referring to FIG. 4K, a cutting operation or a singulation operation may be performed along the scribe lines S to form some semiconductor device packages 1 described and illustrated with reference to FIG. 1A.

The method for manufacturing the semiconductor device package in accordance with some embodiments of the subject application can provide conductive paths with relatively low resistivity (e.g., the current paths Y in the conductive layer 13 as shown in FIG. 1B). The method for manufacturing the semiconductor device package in accordance with some embodiments of the subject application may provide some advantages of FCB technique, e.g., low cost, high throughput and the self-alignment effect of solder.

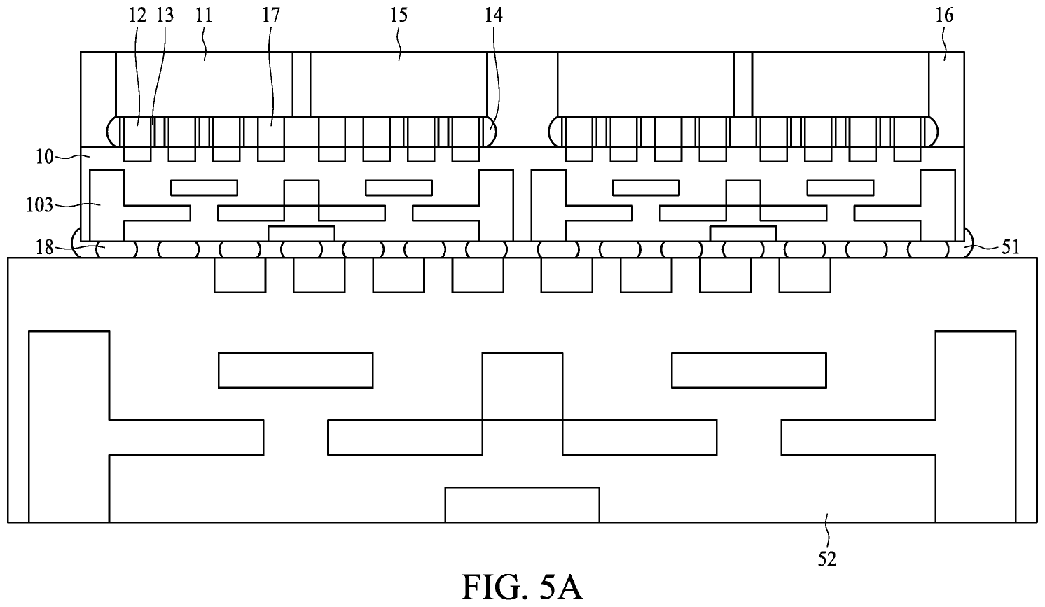

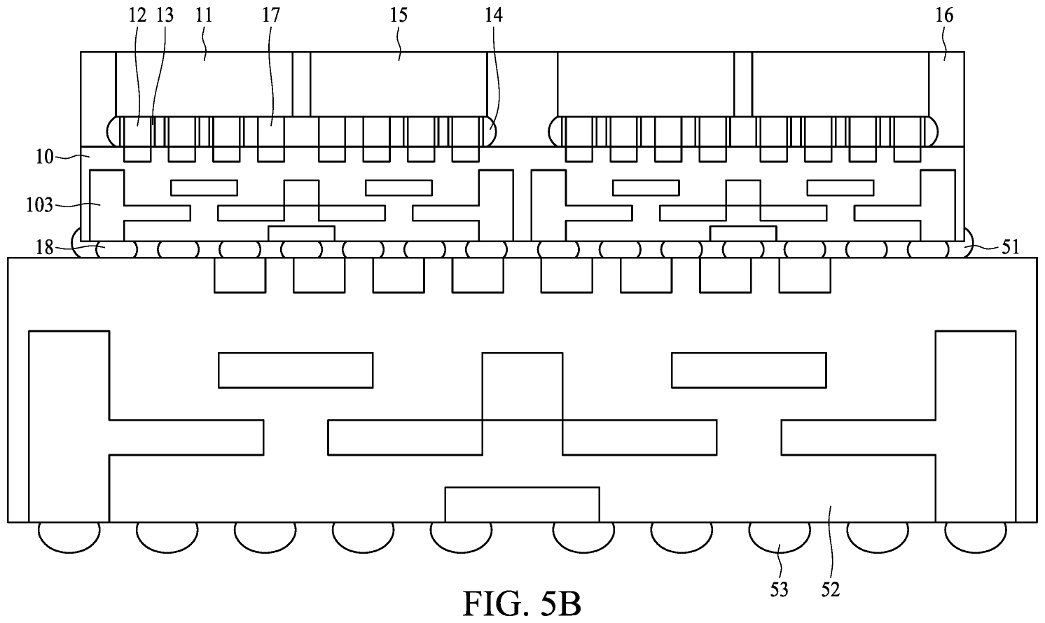

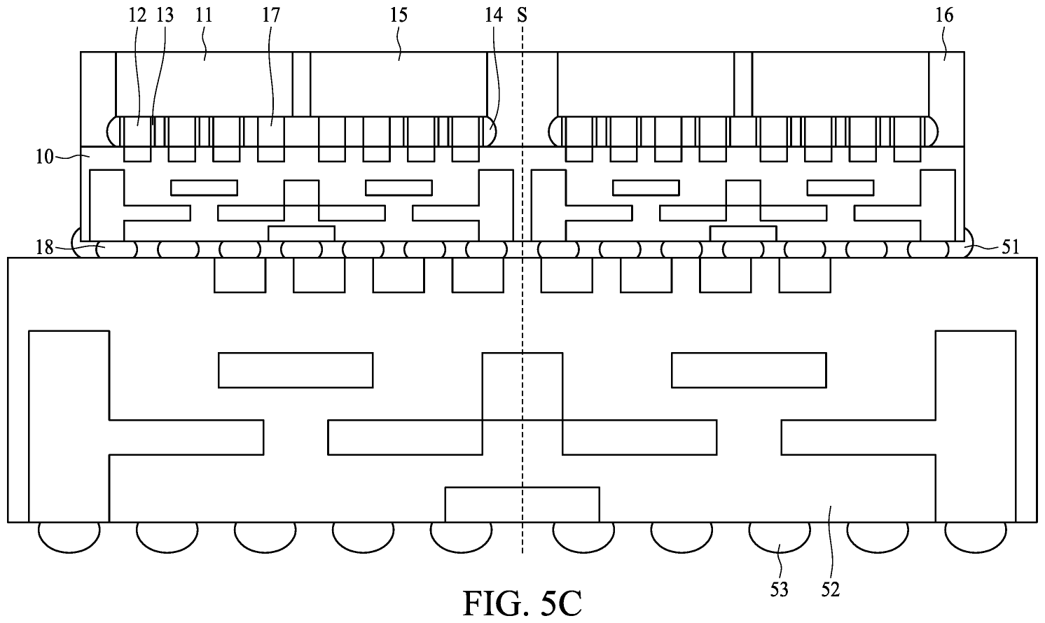

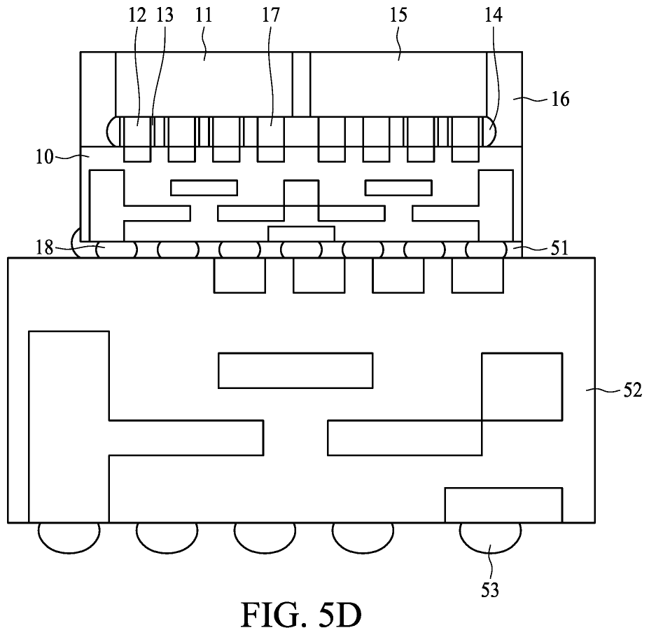

FIG. 5A, FIG. 5B, FIG. 5C and FIG. 5D illustrate various stages of another method for manufacturing a semiconductor device package accordance with some embodiments of the subject application.

Referring to FIG. 5A, the semiconductor device package as described and illustrated with reference to FIG. 4J can be bonded or attached on a substrate 52 by the connection components 18. The substrate 52 may include, for example, a printed circuit board, such as a paper-based copper foil laminate, a composite copper foil laminate, or a polymer-impregnated glass-fiber-based copper foil laminate. The substrate 52 may include an interconnection structure, such as a redistribution layer or a grounding element.

An encapsulant 51 can be formed between the redistribution layer 10 and the substrate 52.

Referring to FIG. 5B, some connection elements 53 may be formed on the substrate 52. The connection elements 53 can be electrically connected to the substrate 52.

Referring to FIG. 5C, a cutting operation or a singulation operation may be performed along the scribe lines S to form some semiconductor device packages 1 described and illustrated with reference to FIG. 5D.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between the highest point and the lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit, and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

As used herein, spatially relative terms, such as “beneath,” “below,” “lower,” “above,” “upper,” “lower,” “left,” “right” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

Ranges can be expressed herein as from one endpoint to another endpoint or between two endpoints. All ranges disclosed herein are inclusive of the endpoints unless specified otherwise.

The foregoing outlines features of several embodiments and detailed aspects of the present disclosure. The embodiments described in the present disclosure may be readily used as a basis for designing or modifying other processes and structures for carrying out the same or similar purposes and/or achieving the same or similar advantages of the embodiments introduced herein. Such equivalent constructions do not depart from the spirit and scope of the present disclosure, and various changes, substitutions, and alterations may be made without departing from the spirit and scope of the present disclosure.

1. A semiconductor device package, comprising:
a redistribution layer (RDL);
a first semiconductor device disposed on the RDL;
a first connection structure disposed between the first semiconductor device and the RDL; and
a first conductive layer surrounding the first connection structure.

2. The semiconductor device package of claim 1, wherein the first conductive layer is in direct contact with the first connection structure.

3. The semiconductor device package of claim 1, wherein the first conductive layer encloses the first connection structure.

4. The semiconductor device package of claim 1, wherein the first conductive layer comprises:
a first portion adjacent to the first semiconductor device; and
a second portion adjacent to the first portion;
wherein the first portion having a width greater than the second portion.

5. The semiconductor device package of claim 4, wherein the first conductive layer further comprises:
a third portion disposed adjacent to the second portion, wherein the third portion having a width greater than the second portion.

6. The semiconductor device package of claim 4, wherein the first portion is tapering.

7. The semiconductor device package of claim 1, further comprising an intermetallic compound (IMC) structure in the first conductive layer.

8. The semiconductor device package of claim 1, wherein the first connection structure comprises:
a first conductive pad;
a second conductive pad disposed on the first conductive pad; and
a first connection element disposed between the first conductive pad and the second conductive pad,
wherein the first connection element includes material different from the first conductive pad.

9. The semiconductor device package of claim 8, wherein the first connection element includes solder material.

10. The semiconductor device package of claim 1, further comprising:
a second connection structure disposed between the first semiconductor device and the RDL; and
a first encapsulant encapsulating the second connection structure,
wherein the second connection structure is in direct contact with the first encapsulant.

11. The semiconductor device package of claim 10, wherein the second connection structure comprises:
a first conductive pad;
a second conductive pad disposed on the first conductive pad; and
a first connection element disposed between the first conductive pad and the second conductive pad of the second connection structure,
wherein the first connection element of the second connection structure includes material different from the first conductive pad of the second connection structure.

12. A semiconductor device package, comprising:
a first conductive pad having a first lateral surface;
a second conductive pad disposed on the first conductive pad and having a first lateral surface; and
a first conductive layer disposed in direct contact with the first lateral surface of the first conductive pad and the first lateral surface of the second conductive pad.

13. The semiconductor device package of claim 12, wherein the conductive layer comprises:
a first portion adjacent to the semiconductor device; and
a second portion adjacent to the first portion;
wherein the first portion having a width greater than the second portion.

14. The semiconductor device package of claim 13, wherein the conductive layer further comprises:
a third portion disposed adjacent to the second portion, wherein the third portion having a width greater than the second portion.

15. The semiconductor device package of claim 13, wherein the first portion is tapering.

16. The semiconductor device package of claim 12, further comprising:
a first connection element disposed between the first conductive pad and the second conductive pad and having a first lateral surface,
wherein the first conductive layer is in direct contact with the first lateral surface of the first connection element.

17. The semiconductor device package of claim 16, wherein the first connection element includes material different from the first conductive pad.

18. The semiconductor device package of claim 16, wherein the first connection element includes solder material.

19. The semiconductor device package of claim 16, further comprising an IMC structure in the first conductive layer.

20. The semiconductor device package of claim 12, further comprising:
a third conductive pad having a first lateral surface;
a fourth conductive pad disposed on the third conductive pad and having a first lateral surface; and
a first encapsulant encapsulating the first lateral surface of the third conductive pad and the first lateral surface of the fourth conductive pad,
wherein the first lateral surface of the third conductive pad and the first lateral surface of the fourth conductive pad are in direct contact with the first encapsulant.

21. The semiconductor device package of claim 20, further comprising:
a second connection element disposed between the third conductive pad and the fourth conductive pad and having a first surface,
wherein the first encapsulant encapsulates the first lateral surface of the second connection element, and
wherein the first lateral surface of the second connection element is in direct contact with the first encapsulant.

22-23. (canceled)

24. The semiconductor device package of claim 7, wherein the IMC structure surrounds the first connection structure.

25. The semiconductor device package of claim 7, wherein the IMC structure encloses the first connection structure.
